(19) United States
(12) Patent Application Publication
(10) Pub. No.: US 2005/0070046 A1
(43) Pub. Date: Mar. 31, 2005

(54) Method of manufacturing electronic device and method of manufacturing electro-optical device

(75) Inventor: Atsushi Saito, Chino-shi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 10/916,621

(22) Filed: Aug. 12, 2004

(30) Foreign Application Priority Data
Aug. 21, 2003 (JP) 2003-297652
Mar. 11, 2004 (JP) 2004-069557

(51) Int. Cl. H01L 21/44

(52) U.S. Cl. 438/106; 438/612

(57) ABSTRACT

A method of manufacturing an electronic device includes: mounting a plurality of electronic components to a thermoplastic resin layer so that the bump electrode is installed in the thermoplastic resin layer, each of the electronic components including a bump electrode; forming a conductor conductively connected with the bump electrode on a surface of the thermoplastic resin layer opposite to a surface on which the electronic components are mounted; and dividing the thermoplastic resin layer in units of each of the electronic components.

Japanese Patent Application No. 2003-297652, filed on Aug. 21, 2003, and Japanese Patent Application No. 2004-69557, filed on Mar. 11, 2004 are hereby incorporated by reference in their entirety.

### BACKGROUND OF THE INVENTION

The present invention relates to a method of manufacturing an electronic device, a method of manufacturing an electro-optical device, an electronic device, and an electro-optical device. More particularly, the present invention relates to a manufacturing technology and a part structure suitable for an electronic component such as a semiconductor IC chip.

In various types of electronic instruments, an electronic component such as a semiconductor IC is generally mounted on a circuit board or the like to make up a part of an electronic circuit. As a method for mounting an electronic component on a circuit board or the like, various methods have been proposed. For example, a mounting method in which bump electrodes of an electronic component are bonded to conductive pads on a circuit board and the space between the electronic component and the circuit board is filled and sealed with an underfill resin has been known as the most general method.

As a mounting method widely used for a liquid crystal display device or the like, a method of mounting an electronic component through an anisotropic conductive film (ACF) has been known. In this method, an electronic component is pressed against a circuit board or a glass substrate, which makes up a liquid crystal panel, through an ACF in which conductive fine particles are dispersed in a thermosetting resin while heating the electronic component using a pressure heating head. This causes bump electrodes of the electronic component to be conductively connected with terminals on the substrate through the conductive particles, and the conductive connection state is maintained by allowing the thermosetting resin to be cured in this state.

A method for forming an electronic device has been known in which a circuit board in which conductive pads are formed on one surface of a substrate formed of a thermoplastic resin is provided, and an IC chip provided with bump electrodes is pressed against the surface of the circuit board opposite to the conductive pad formation surface under heating, whereby the bump electrodes are inserted into the thermoplastic resin of the circuit board and secured in a state in which the ends of the bump electrodes are conductively connected with the conductive pads from the inside of the circuit board (see Japanese Patent Application Laid-open No. 2003-124259, for example).

However, in the method of filling the space between the electronic component and the circuit board with the underfill resin, it may take time to inject the underfill resin.

In the mounting method using the ACF, since the conductive particles must be reduced in size as the pitch between the terminals is reduced, the cost of the ACF may be increased.

The method disclosed in Japanese Patent Application Laid-open No. 2003-124259 may make it difficult to align the bump electrodes of the IC chip and the conductive pads of the circuit board.

### BRIEF SUMMARY OF THE INVENTION

A method of manufacturing an electronic device according to one aspect of the present invention includes:
mounting a plurality of electronic components to a thermoplastic resin layer so that the bump electrode is installed in the thermoplastic resin layer, each of the electronic components including a bump electrode;
forming a conductor conductively connected with the bump electrode on a surface of the thermoplastic resin layer opposite to a surface on which the electronic components are mounted; and
dividing the thermoplastic resin layer in units of each of the electronic components.

A method of manufacturing an electro-optical device according to another aspect of the present invention includes:
mounting an electronic device manufactured by using the manufacturing method as defined in claim 1 on a circuit board by thermocompression bonding; and
mounting the circuit board on an electro-optical panel.

A method of manufacturing an electro-optical device according to a further aspect of the present invention includes:
mounting an electronic device manufactured by using the manufacturing method as defined in claim 1 on a substrate which forms an electro-optical panel by thermocompression bonding.

### BRIEF DESCRIPTION OF THE SEVERAL VIEWS OF THE DRAWING

FIGS. 1A to 1C are illustrative of a method of manufacturing an electronic device according to a first embodiment of the present invention.

FIGS. 2A to 2C are illustrative of a method of manufacturing an electronic device according to a second embodiment of the present invention.

FIGS. 3A to 3D are illustrative of a method of manufacturing an electronic device according to a modification of the second embodiment of the present invention.

FIGS. 4A to 4C are illustrative of a method of manufacturing an electronic device according to a third embodiment of the present invention:

FIGS. 5A to 5D are illustrative of a method of manufacturing an electronic device according to a fourth embodiment of the present invention.

FIG. 6 is another view illustrating a method of manufacturing an electronic device according to the second embodiment of the present invention.

FIG. 7 is illustrative of a method of manufacturing an electronic device according to a fifth embodiment of the present invention.

FIGS. 8A to 8C are illustrative of a method of manufacturing an electronic device according to the fifth embodiment of the present invention.

FIG. 9 is illustrative of a mounting structure of an electro-optical device according to a sixth embodiment of the present invention.

FIG. 10 is illustrative of a mounting structure of an electro-optical device according to a seventh embodiment of the present invention.

FIG. 11 is illustrative of a mounting structure of an electro-optical device according to an eighth embodiment of the present invention.

### DETAILED DESCRIPTION OF THE EMBODIMENT

The present invention may provide a method of easily, inexpensively, and efficiently manufacturing an electronic device in which an electronic component is mounted on a substrate while ensuring high electrical reliability.

(1) A method of manufacturing an electronic device according to one embodiment of the present invention includes:
mounting a plurality of electronic components to a thermoplastic resin layer so that the bump electrode is installed in the thermoplastic resin layer, each of the electronic components including a bump electrode;
forming a conductor conductively connected with the bump electrode on a surface of the thermoplastic resin layer opposite to a surface on which the electronic components are mounted; and
dividing the thermoplastic resin layer in units of each of the electronic components.

According to this embodiment, since the conductor can be formed collectively by mounting the electronic components in the thermoplastic resin layer, the electronic devices can be efficiently manufactured, whereby the manufacturing cost can be reduced. As the electronic component in the present invention, a semiconductor IC chip, a ceramic electronic component (ceramic capacitor or the like), and the like can be given.

(2) With this method of manufacturing an electronic device, in the step of mounting the electronic components, the electronic component or the thermoplastic resin layer may be heated.

Since at least a part of the thermoplastic resin in contact with the bump electrode can be caused to soften or melt by heating the electronic component or the thermoplastic resin layer, the bump electrode can be easily and securely installed in the thermoplastic resin.

(3) With this method of manufacturing an electronic device, in the step of mounting the electronic components, the electronic components may be mounted so that the bump electrode passes through the thermoplastic resin layer and is exposed from the surface of the thermoplastic resin layer opposite to the surface on which the electronic components are mounted.

According to this feature, since the bump electrode is exposed from the surface of the thermoplastic resin layer in the step of mounting the electronic components, the alignment operation of the conductor in the step of forming the conductor can be facilitated, and the conductor can be easily and securely conductively connected with the bump electrode.

(4) With this method of manufacturing an electronic device, in the step of mounting the electronic components, the electronic components may be mounted so that the bump electrode is conductively connected with a conductor layer which has been disposed in advance on the surface of the thermoplastic resin layer opposite to the surface on which the electronic components are mounted, and in the step of forming the conductor, the conductor may be formed by patterning the conductor layer.

According to this feature, the bump electrode can be securely caused to be conductively connected with the conductor layer in the step of mounting the electronic components by forming the conductor layer over the entire surface of the thermoplastic resin layer or in a range greater than the bump electrode, and the conductor can be formed into a desired shape or pattern in the step of forming the conductor by patterning the conductor layer. Therefore, alignment in the step of mounting the electronic components can be made easier than the case of forming a patterned conductor on the surface of the thermoplastic resin layer.

(5) This method of manufacturing an electronic device may include,
before the step of mounting the electronic components, forming a penetrating hole in the thermoplastic resin layer and disposing a conductive material in the penetrating hole, and
in the step of mounting the electronic components, the bump electrode may be inserted into the penetrating hole and conductively connected with the conductive material.

According to this feature, since the bump electrode and the conductor can be conductively connected securely through the conductive material, even if the thickness of the thermoplastic resin layer is greater than the projection height of the bump electrode, by forming the penetrating hole in the thermoplastic resin layer and disposing the conductive material in the penetrating hole in the step of forming the penetrating hole, the degrees of freedom on the structure of the electronic device can be increased, and electrical reliability can be increased. In particular, the conductor layer may be disposed on the surface of the thermoplastic resin layer opposite to the surface on which the electronic components are mounted, the conductive material may be disposed in the penetrating hole in this state so that the conductive material is conductively connected with the conductor layer, and the conductor may be formed by patterning the conductor layer after mounting the electronic components.

(6) With this method of manufacturing an electronic device, in the step of mounting the electronic components, the thermoplastic resin layer may be formed to enclose the electronic components by molding.

The shape of the thermoplastic resin layer can be specified with high accuracy by forming the thermoplastic resin layer by molding. For example, the bump electrode can be securely exposed from the surface of the thermoplastic resin layer opposite to the surface on which the electronic components are mounted. In this case, the thermoplastic resin layer can be easily formed by using an insert molding method in which the electronic components are disposed inside a die. As the molding method, an injection molding method, a blow molding method, or the like may be used.

(7) With this method of manufacturing an electronic device, in the step of mounting the electronic components, the molding may be performed in a state in which the electronic components are supported by a supporter.

According to this feature, since the electronic components are integrally supported by the supporter, handling can be facilitated and the thermoplastic resin layer can be formed over the electronic components with high accuracy.

(8) With this method of manufacturing an electronic device,
the supporter may be formed of a conductive material and conductively connected with the bump electrode, and
in the step of forming the conductor, the conductor may be formed by patterning the supporter.

According to this feature, since it is unnecessary to remove the supporter and the conductor can be formed by merely patterning the supporter, the number of steps can be reduced, whereby the manufacturing cost can be reduced.

(9) With this method of manufacturing an electronic device, in the step of forming the conductor, the conductor may be formed by applying a fluid material to the surface of the thermoplastic resin layer opposite to the surface on which the electronic components are mounted, and curing the fluid material.

This enables alignment to be facilitated, whereby the conductor can be formed at accurate positions. The fluid material may be cured by a curing effect due to heating, irradiation, drying, baking, or a chemical reaction depending on the characteristics of the fluid material.

(10) With this method of manufacturing an electronic device, in the step of forming the conductor, the fluid material in the form of liquid may be discharged as a droplet.

This enables accuracy of the application position and the application amount of the fluid material to be increased. The droplet may be discharged by using a piezoelectric type or thermal-bubble type ink-jet head.

(11) With this method of manufacturing an electronic device, in the step of forming the conductor, the fluid material in the form of paste may be printed.

This enables the conductor to be efficiently formed at low cost. As the printing method, screen printing can be given.

(12) With this method of manufacturing an electronic device,
the step of forming the conductor may include forming a resist layer which has a patterned opening on the surface of the thermoplastic resin layer opposite to the surface on which the electronic components are mounted, and
the conductor may be formed on a portion of the thermoplastic resin layer exposed from the opening.

This enables the conductor to be formed conforming to the design.

(13) With this method of manufacturing an electronic device,
the step of forming the conductor may include discharging a solvent containing conductive particles, and
the resist layer may be formed so that an upper surface of the resist layer has an affinity to the solvent lower than an affinity of the surface of the thermoplastic resin layer opposite to the surface on which the electronic components are mounted.

This enables the conductor to be efficiently formed.

(14) This method of manufacturing an electronic device may include removing the resist layer after forming the conductor.

This enables manufacture of a highly reliable electronic device.

(15) A method of manufacturing an electro-optical device according to another embodiment of the present invention includes:
mounting an electronic device manufactured by using the above manufacturing method on a circuit board by thermocompression bonding; and
mounting the circuit board on an electro-optical panel.

In the method of manufacturing an electro-optical device according to this embodiment, since the electronic device is mounted by the thermocompression bonding, the thermoplastic resin is soften or melt. Therefore, the electronic device can be easily mounted on the circuit board. In particular, if resin exposed from the surface of the circuit board is a thermoplastic resin, the resin of the circuit board and the thermoplastic resin layer of the electronic device easily melt and adhere, whereby the electronic device can be extremely easily mounted. The electronic component may include a circuit which generates a drive signal for driving the electro-optical device.

(16) A method of manufacturing an electro-optical device according to a further embodiment of the present invention includes:
mounting an electronic device manufactured by using the above manufacturing method on a substrate which forms an electro-optical panel by thermocompression bonding.

In the method of manufacturing an electro-optical device according to this embodiment, since the electronic device is mounted by the thermocompression bonding, the thermoplastic resin is soften or melt. Therefore, the electronic device can be easily mounted on the electro-optical panel. As the material for the substrate which forms the electro-optical panel, glass, quartz, plastic, ceramic, and the like can be given. The electronic device can be easily mounted regardless of which of these materials is used. Each of the electronic components may include a circuit which generates a drive signal for driving the electro-optical device.

The electronic device includes an electronic component including a bump electrode, a thermoplastic resin layer formed on a bump electrode formation surface of the electronic component, and a conductor formed on the thermoplastic resin layer and conductively connected with the bump electrode. The electronic device may be used for an electro-optical device. In more detail, an electro-optical device according to an embodiment of the present invention includes an electro-optical panel and a circuit board mounted on the electro-optical panel, and the electronic device according to the above embodiment of the present invention may be mounted on the circuit board. The electro-optical device may include an electro-optical panel and the electronic device according to the above embodiment of the present invention mounted on a substrate which forms the electro-optical panel. In the latter case, the electro-optical device may further include a circuit board conductively connected with the electronic device. The electronic component may include a circuit which generates a drive signal for driving the electro-optical device.

The embodiments according to the present invention are described below with reference to the drawings. Each drawing to be referred to in the following description schematically shows a structure of each embodiment of the present invention. The shape and dimensional ratio of the structure do not necessarily represent the actual shape and dimensional ratio.

First Embodiment

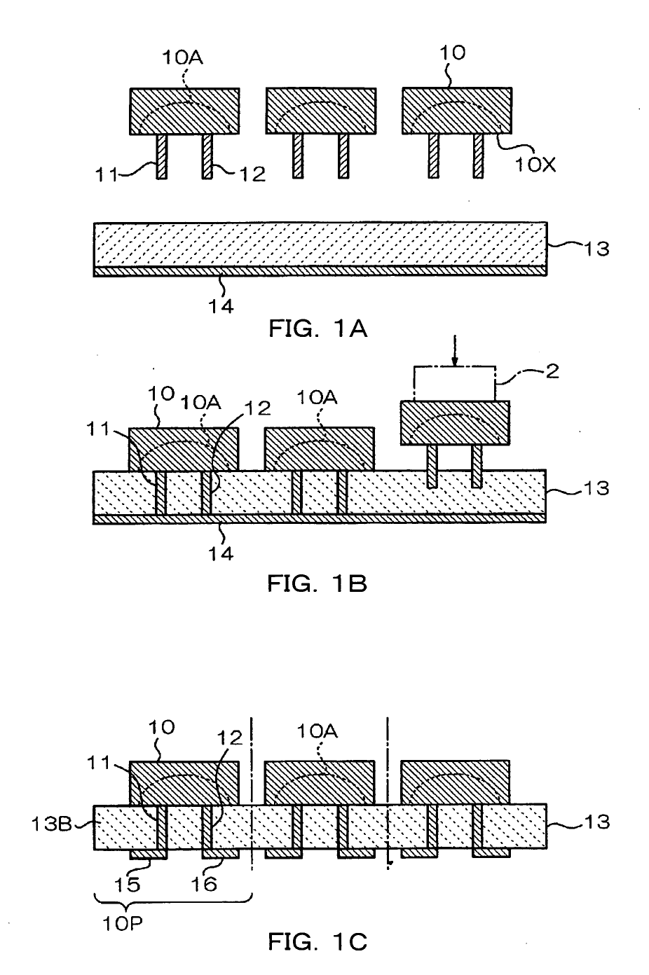

The first embodiment according to the present invention is described below with reference to FIGS. 1A to 1C. In the present embodiment, as shown in FIG. 1A, a plurality of electronic components 10, each of which includes an electronic structure region 10A consisting of a semiconductor structure, a conductor pattern, and the like, are provided. The electronic component 10 may be a semiconductor chip which is formed of a silicon single crystal, a compound semiconductor single crystal, or the like and includes a predetermined electronic circuit structure as the electronic structure region 10A, or may be a ceramic stack (ceramic substrate) which includes a number of ceramic layers and conductive layers disposed between the ceramic layers and in which the conductive layers are formed in a predetermined conductor pattern as the electronic structure region 10A. The electronic component 10 is formed to a thickness of about 100 μm to 800 μm when the electronic structure substrate 10 is a semiconductor chip, and is formed to a thickness of about 1 to 5 mm when the electronic structure substrate 10 is a ceramic stack.

Bump electrodes 11 and 12 (projection electrodes) are formed on a mounting surface 10X of the electronic component 10 in units of the electronic structure regions 10A. The number of bump electrodes 11 and 12 is arbitrary, and may be one or three or more. In the example shown in FIG. 1, two bump electrodes are formed in units of the electronic structure regions 10A. It suffices that the bump electrodes 11 and 12 be formed of a conductor. For example, the bump electrodes 11 and 12 are formed of a metal such as Cu, Ni, Au, Ag, or Al. As the structure of the bump electrode, the surface of a projecting section of a metal layer formed of Cu, Ni, Al, or the like may be covered with a thin film formed of Au, Ag, Sn, or the like. The bump electrodes 11 and 12 have a diameter of about 10 μm to 30 μm and are formed at a pitch of about 30 μm to 50 μm, for example. The projection height of the bump electrodes 11 and 12 is about 10 μm to 50 μm. The projection height is set at a value almost the same as the thickness of a thermoplastic resin layer described later.

The electronic component 10 configured as described above is mounted in a thermoplastic resin layer 13. The thermoplastic resin layer 13 is formed of a thermoplastic resin such as a polyester resin, a polyamide resin, an aromatic polyester resin, an aromatic polyamide resin, a tetrafluoroethylene resin, or a polyimide resin. In the present embodiment, the thermoplastic resin layer 13 is formed to a thickness of 20 μm to 50 μm, and typically about 30 μm. The thermoplastic resin layer 13 may have a thickness the same as the projection height of the bump electrodes 11 and 12, or may have a thickness about 1 μm to 10 μm greater than the projection height of the bump electrodes 11 and 12. A conductor layer 14 formed of a metal such as Cu, Al, or Au or other conductor is formed on one surface of the thermoplastic resin layer 13. The conductor layer 14 may be merely placed on the surface of the thermoplastic resin layer 13, or may be bonded (adhering) to the surface of the thermoplastic resin layer 13. The conductor layer 14 is formed to a thickness of 1 μm to 20 μm, and typically about 10 μm, for example.

The electronic component 10 is mounted in a state in which the mounting surface 10X of the electronic component 10 faces the thermoplastic resin layer 13 (electronic components mounting step). For example, the thermoplastic resin layer 13 and the conductor layer 14 are pressed against the mounting surface 10X of the electronic component 10. In this case, the electronic component 10 or the thermoplastic resin layer 13 may be heated. For example, the electronic component 10 is heated by causing a heating head or a heating stage to come in contact with the surface of the electronic component 10 opposite to the mounting surface 10X, or the thermoplastic resin layer 13 is heated by causing a heating head or a heating stage to come in contact with the conductor layer 14. The thermoplastic resin layer 13 and the conductor layer 14 may be pressed against the electronic component 10 using a roller or the like. In this case, the thermoplastic resin layer 13 may be heated by using the roller. The heating temperature is set to be equal to or higher than the softening temperature of the thermoplastic resin layer 13, but less than the melting temperature of the bump electrodes 11 and 12 or the heat-resistant temperature of the electronic component 10. The heating temperature is preferably in the range of 120° C. to 350° C. FIG. 1B shows a state in which the electronic components 10 are sequentially mounted in the thermoplastic resin layer 13 using an overheating pressure head 2.

When the electronic component 10 is mounted in the thermoplastic resin layer 13 as described above, the bump electrodes 11 and 12 are inserted into the thermoplastic resin layer 13. The bump electrodes 11 and 12 are installed in the thermoplastic resin layer 13 when the mounting surface 10X of the electronic component 10 adheres to the thermoplastic resin layer 13. As shown in FIG. 1B, the bump electrodes 11 and 12 are conductively connected with the conductor layer 14 when the electronic components mounting step is completed. This conductive contact state is realized by applying a stress equal to or greater than the stress necessary for the bump electrodes 11 and 12 to push through the thermoplastic resin layer 13 which has been softened or melted by heating between the electronic component 10 and the conductor layer 14. The bump electrodes 11 and 12 and the conductor layer 14 may be alloyed by heating. In this case, the heating temperature differs depending on the materials for the bump electrodes 11 and 12 and the conductor layer 14, and may be about 200° C. to 400° C.

As shown in FIG. 1C, conductors 15 and 16 conductively connected with the bump electrodes 11 and 12 are formed by patterning the conductor layer 14 (conductor formation step). As the patterning method, a method in which a mask is formed by a conventional photolithographic method or the like using a resist or the like, and the conductor layer 14 is etched using the mask can be given. The conductors 15 and 16 may be terminals such as conductive pads, or may be an interconnect pattern formed in a predetermined pattern.

The thermoplastic resin layer 13 is divided in units of the electronic components 10 as indicated by one-dot lines shown in FIG. 1C to form a plurality of electronic devices 10P (part dividing step). As the dividing method in this step, a dicing method, a laser cutting method, or the like may be used.

The electronic device 10P includes the electronic component 10 including the electronic structure region 10A, a thermoplastic resin split layer 13B, and the conductors 15 and 16 conductively connected with the bump electrodes 11 and 12. The electronic device 10P can be easily mounted by using a method in which the thermoplastic resin layer 13 is pressed against a mounting target such as a circuit board while heating the electronic component 10 using a pressure heating head (not shown), thereby causing the thermoplastic resin split layer 13B to soften or melt to adhere to the mounting target.

In the present embodiment, since the conductors 15 and 16 can be formed collectively on the thermoplastic resin layer 13 in which the electronic components 10 are mounted, the electronic devices can be efficiently manufactured, whereby the manufacturing cost can be reduced. Moreover, since the dividing operation of the thermoplastic resin layer 13 can be easily performed, handling and management of the electronic devices 10P such as transportation, storage, and supply are facilitated by handling the electronic devices 10P integrated by the thermoplastic resin layer 13 after forming the conductors 15 and 16. For example, the mounting units integrated by the thermoplastic resin layer 13 may be supplied to an assembly line for incorporating the electronic devices 10P, and the electronic devices 10P may be incorporated while dividing the thermoplastic resin layer 13 at an incorporation position.

In the present embodiment, since the conductor layer 14 is formed in advance on one surface of the thermoplastic resin layer 13, and the bump electrodes 11 and 12 are caused to conductively come in contact with the conductor layer 14 from the inside of the thermoplastic resin layer 13 when mounting the electronic component 10 in the thermoplastic resin layer 13, the bump electrodes 11 and 12 can be securely caused to conductively come in contact with the conductor layer 14 without alignment or the like. In this case, the conductor layer 14 may be entirely formed on one surface of the thermoplastic resin layer 13. However, the conductor layer 14 is not necessarily formed on the entire surface. For example, the conductor layer 14 may be formed in the shape of an island so as to spread around the formation regions of the bump electrodes 11 and 12 to a certain extent, or may be formed in the shape of an island corresponding to the electronic structure regions 10A. In either case, the conductor layer 14 can be securely caused to conductively come in contact with the bump electrodes 11 and 12 by forming the conductor layer 14 so as to include a region in which the conductor layer 14 overlaps the bump electrodes 11 and 12 and to cover a wide range around the overlapping region.

Second Embodiment

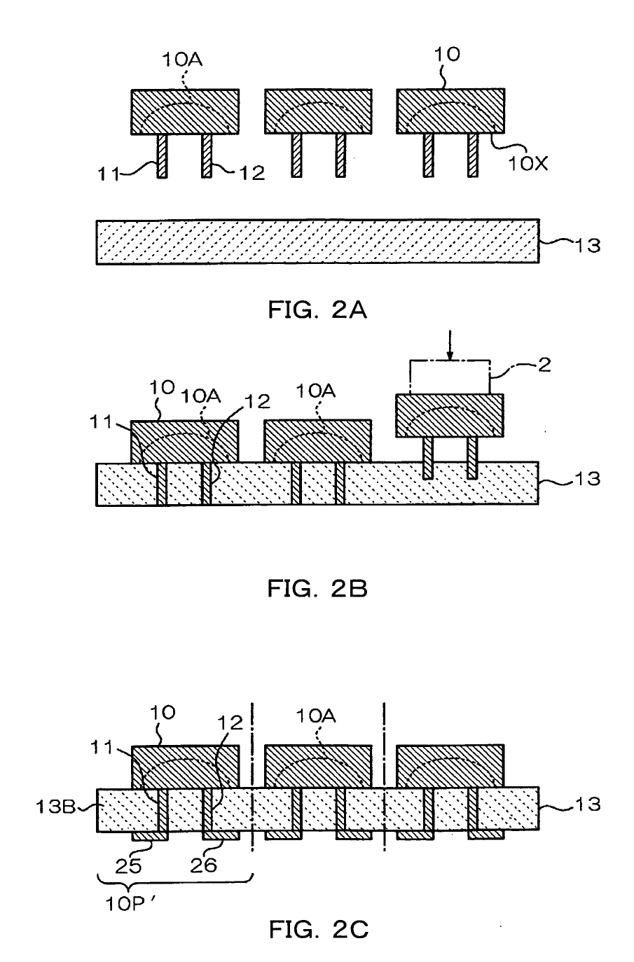

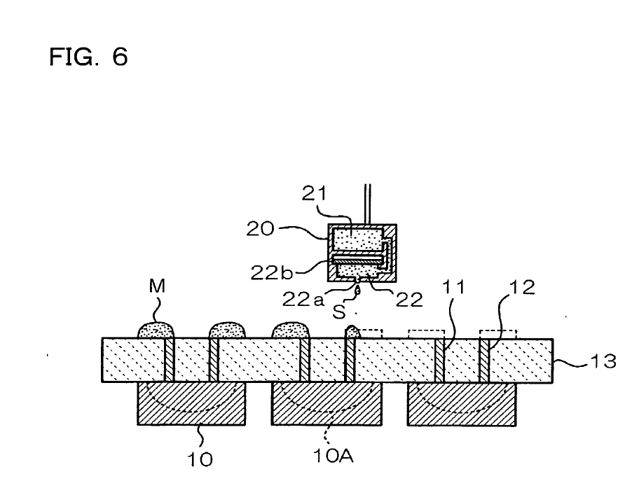

The second embodiment according to the present invention is described below with reference to FIGS. 2A to 2C and FIG. 6. In the present embodiment, constituent elements the same as the constituent elements in the first embodiment are denoted by the same symbols. Description of these constituent elements is omitted. In the present embodiment, as shown in FIG. 2A, the electronic components 10 are mounted in the thermoplastic resin layer 13 by using the same method as in the first embodiment. However, in the present embodiment, a conductor layer is not formed on the surface of the thermoplastic resin layer 13. As shown in FIG. 2B, in this electronic components mounting step, the electronic components 10 are mounted so that the ends of the bump electrodes 11 and 12 are exposed from the surface of the thermoplastic resin layer 13 opposite to the electronic components 10.

As shown in FIG. 2C, conductors 25 and 26 are formed on the surface of the thermoplastic resin layer 13 so that the conductors 25 and 26 are conductively connected with the exposed bump electrodes 11 and 12. The conductors 25 and 26 may be formed by using the same method as in the first embodiment. In the present embodiment, the conductors 25 and 26 are formed by applying a fluid material to the surface of the thermoplastic resin layer 13 and curing the applied fluid material. In the formation method for the conductors 25 and 26 used in the conductor formation step in the present embodiment, a liquid material is applied by discharging a droplet S onto the surface of the thermoplastic resin layer 13 from a discharge head 20 shown in FIG. 6.

The discharge head 20 has essentially the same structure as that used for an ink-jet printer. In more detail, a container chamber 21 which contains a liquid material and a discharge chamber 22 which communicates with the container chamber 21 are provided inside the discharge head 20. A liquid material supply line is connected with the container chamber 21. A piezoelectric inner wall section 22b formed of an operable piezoelectric is provided so as to face the discharge chamber 22, and a discharge port 22a which communicates with the outside is formed. The piezoelectric inner wall section 22b is formed so as to be deformed corresponding to a drive voltage. The liquid material flows into the discharge chamber 22 from the container chamber 21 when the piezoelectric inner wall section 22b is bent outward and the capacity of the discharge chamber 22 is increased, and the droplet S of the liquid material is discharged from the discharge port 22a when the piezoelectric inner wall section 22b is bent inward and the capacity of the discharge chamber 22 is decreased.

The liquid material is a material in which conductive particles are dispersed in a solvent, for example. The application amount can be precisely set by the number of discharges of the droplets S. The thermoplastic resin layer 13 and the discharge head 20 can be relatively moved so that the impact position of the droplet S discharged from the discharge head 20 can be controlled. Therefore, a liquid material M can be applied to the surface of the thermoplastic resin layer 13 at an arbitrary position in an arbitrary shape by adjusting the number of discharges and the impact position of the droplets S.

The liquid material M is cured by drying or sintering to form the conductors 25 and 26 shown in FIG. 2C.

According to the above-described conductor formation method, the conductors 25 and 26 can be precisely formed without patterning. Moreover, this method has an advantage in that the alignment operation can be facilitated since the conductors 25 and 26 can be formed using the exposed bump electrodes 11 and 12 as targets.

In the above-described conductor formation step, a conductive paste may be used as the fluid material. The conductive paste may be printed on the surface of the thermoplastic resin layer 13 by using a printing method (screen printing method, for example), and the conductive paste may be cured by heating or allowing the conductive paste to stand in this state. This method enables the conductors 25 and 26 to be inexpensively and efficiently formed by using the printing method.

An electronic device 10P′ formed by the present embodiment has essentially the same structure and effect as those of the electronic device 10P in the first embodiment.

In this conductor formation step, the fluid material is applied to the surface of the thermoplastic resin layer 13. As the fluid material, powder or the like may be used instead of the liquid material or paste material. As the curing method for the fluid material, various methods such as a drying treatment which volatilizes a solvent, a sintering treatment which causes a welding or sintering effect to occur by heating, or a treatment which causes curing by a chemical reaction may be applied corresponding to the material characteristics.

Modification

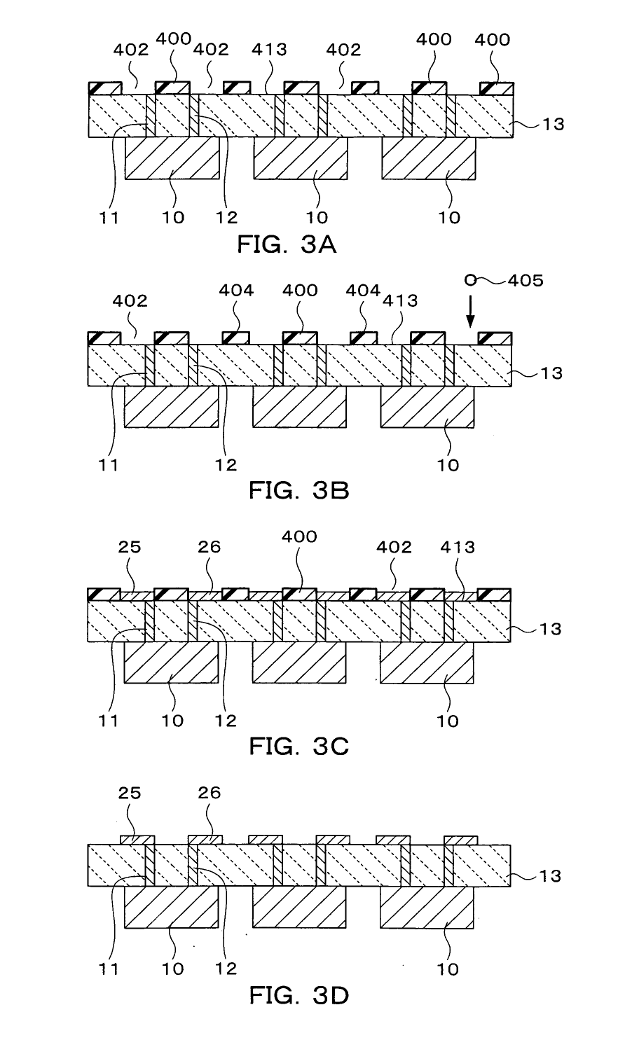

A modification of the second embodiment is described below with reference to the drawings. FIGS. 3A to 3D are illustrative of this modification. In this modification, as shown in FIG. 3A, the step of forming the conductors 25 and 26 includes a step of forming a resist layer 400 having patterned openings 402 on the surface of the thermoplastic resin layer 13 opposite to the electronic components 10. The step of forming the resist layer 400 is not particularly limited. The resist layer 400 may be formed by using a conventional method. For example, a resist layer may be formed on the entire surface of the thermosetting resin layer 13, and the resist layer 400 having the openings 402 may be formed by removing a part of the resist layer. In this case, a part of the resist layer may be removed by an exposure step and a development step, for example. The opening 402 may be formed in the shape of a groove. In this modification, the conductors 25 and 26 are formed on sections 413 of the thermosetting resin layer 13 exposed in the openings 402 (see FIG. 3C). In other words, the conductors 25 and 26 may be formed in the openings 402. This enables the conductors 25 and 26 to be formed to have a width the same as the width of the openings 402. Specifically, the width of the conductors 25 and 26 can be limited by the openings 402. Therefore, the conductors 25 and 26 can be formed conforming to the design.

In this modification, the conductors 25 and 26 may be formed by using a solvent 405 containing conductive fine particles, as shown in FIG. 3B. In more detail, the conductors 25 and 26 may be formed by discharging the solvent 405 containing conductive fine particles. This enables the conductors 25 and 26 to be efficiently formed. As shown in FIG. 3B, the solvent 405 may be discharged from above the opening 402. In other words, the solvent 405 may be discharged onto the exposed section 413. This enables the conductors 25 and 26 to be formed on the exposed sections 413. The conductive fine particles may be formed of a material which is rarely oxidized and has low electrical resistance, such as gold or silver. “Perfect Gold” manufactured by Vacuum Metallurgical Co., Ltd. may be used as a solvent containing gold fine particles, and “Perfect Silver” manufactured by Vacuum Metallurgical Co., Ltd. may be used as a solvent containing silver fine particles. There are no specific limitations to the size of the fine particles. The fine particles used herein refer to particles which can be discharged together with a dispersion medium. The conductive fine particles may be covered with a coating material in order to prevent occurrence of a reaction. The solvent 405 may be dried to only a small extent and have resolubility. The conductive fine particles may be uniformly dispersed in the solvent 405. The step of forming the conductors 25 and 26 may include discharging the solvent 405. The solvent 405 containing conductive fine particles may be discharged by using an ink-jet method, a Bubble Jet (registered trademark) method, or the like. The solvent 405 may be discharged by mask printing or screen printing, or by using a dispenser. A conductive member may be formed by performing a step of volatilizing the dispersion medium, a step of decomposing the coating material which protects the conductive fine particles, and the like. The conductors 25 and 26 may be formed as shown in FIG. 3C by performing these steps or by repeating these steps.

In this modification, the resist layer 400 may be formed so that an upper surface 404 of the resist layer 400 has an affinity to the solvent 405 lower than that of the surface of the thermoplastic resin layer 13 opposite to the electronic components 10. In other words, the resist layer 400 may be formed so that the upper surface 404 has an affinity to the solvent 405 lower than that of the exposed section 413. Since this allows the solvent 405 to easily enter the opening 402 in the resist layer 400, the conductors 25 and 26 can be efficiently manufactured even if the width of the opening 402 is smaller than the diameter of the droplet of the solvent 405. Specifically, a conductor having a width smaller than the diameter of the droplet of the solvent 405 can be efficiently manufactured. For example, the resist layer 400 may be formed by utilizing a material having an affinity to the solvent 405 lower than that of the resin which makes up the thermoplastic resin layer 13.

In this modification, the manufacturing method may include a step of removing the resist layer 400 after forming the conductors 25 and 26, as shown in FIG. 3D. Since the conductive fine particles on the resist layer 400 can be removed by removing the resist layer 400, a highly reliable electronic device in which the conductors 25 and 26 are rarely short-circuited can be formed.

Third Embodiment

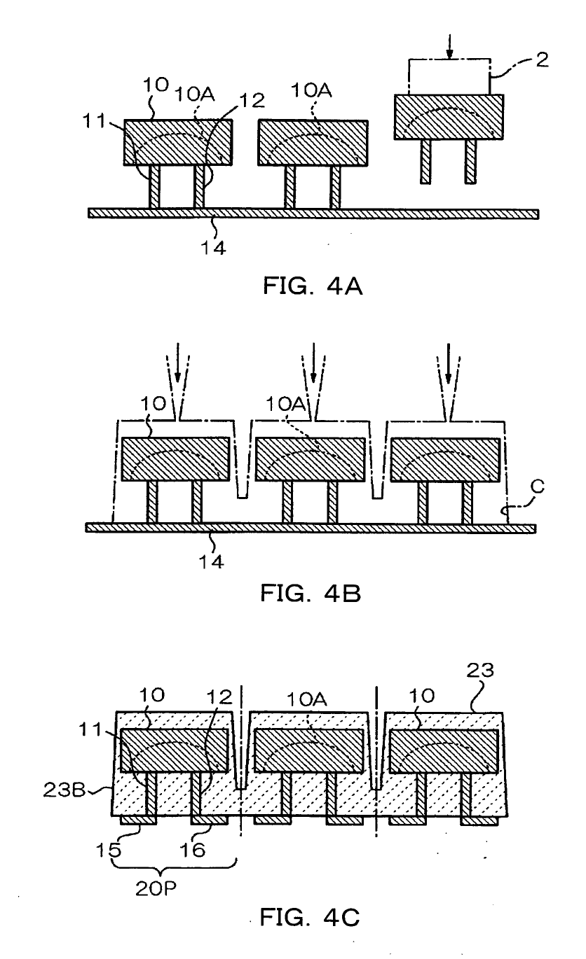

The third embodiment according to the present invention is described below with reference to FIGS. 4A to 4C. In the present embodiment, constituent elements the same as the constituent elements in the first embodiment or the second embodiment are denoted by the same symbols. Description of these constituent elements is omitted.

In the present embodiment, as shown in FIG. 4A, the bump electrodes 11 and 12 of the electronic components 10 are compression-bonded to a conductor layer 14 formed of metal foil or the like. The bump electrodes 11 and 12 and the conductor layer 14 may be alloyed by heating the electronic component 10 or the conductor layer 14.

A thermoplastic resin layer is formed by molding so as to enclose the electronic components 10. In more detail, the electronic components 10 and the conductor layer 14 are placed in a die so that a cavity C is formed between the electronic components 10 and the conductor layer 14 as indicated by a one-dot line shown in FIG. 4B, and a molten resin is injected into the cavity C as indicated by the arrow by using an injection molding machine (not shown) or the like. The injected resin is cured due to a decrease in the temperature inside the die, whereby a thermoplastic resin layer 23 shown in FIG. 4C is formed.

In the present embodiment, since the thermoplastic resin layer 23 is formed by molding, the thermoplastic resin layer 23 can be formed into a desired shape corresponding to the shape of the die. In the example shown in the drawings, the thermoplastic resin layer 23 is formed to entirely enclose the electronic components 10. In the present invention, it suffices that the thermoplastic resin layer 23 be formed so that the space between the mounting surface 10X of the electronic component 10 and the surface of the conductor layer 14 with which the bump electrodes 11 and 12 are conductively in contact is filled with the thermoplastic resin layer so that the bump electrodes 11 and 12 are entirely enclosed.

As shown in FIG. 4C, the conductors 15 and 16 conductively connected with the bump electrodes 11 and 12 are formed by patterning the conductor layer 14 using the same method as in the first embodiment. Then, electronic devices 20P, each of which includes the electronic component 10, a thermoplastic resin split layer 23B, and the conductors 15 and 16, are formed by dividing the thermoplastic resin layer 23 in the same manner as in the first embodiment.

In the present embodiment, since the electronic components 10 are integrated by the conductor layer 14 and the thermoplastic resin layer 23 is formed by molding in this state, handling can be facilitated and productivity can be increased.

Fourth Embodiment

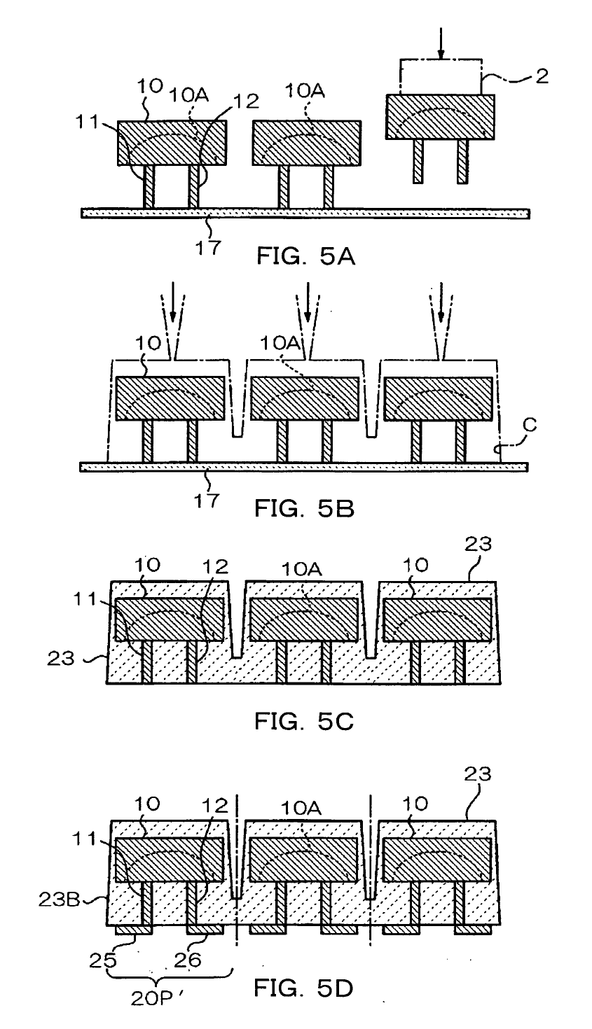

The fourth embodiment according to the present invention is described below with reference to FIGS. 5A to 5D. In the present embodiment, as shown in FIG. 5A, the electronic components 10 are integrally supported by a supporter by compression bonding the bump electrodes 11 and 12 of the electronic components 10 to a supporter 17. The supporter 17 may be formed of a conductor such as a metal in the same manner as the conductor layer 14 in the third embodiment, or may be formed of an arbitrary material other than a conductor. However, the supporter 17 may be formed of a metal (metal sheet or the like) in order to provide the supporter 17 with excellent adhesion to the bump electrodes 11 and 12 and to remove the supporter 17 in a step described later.

As shown in FIG. 5B, the thermoplastic resin layer 23 is formed by using the same method as in the third embodiment. As shown in FIG. 5C, the supporter 17 is removed by etching or the like. As shown in FIG. 5D, the conductors 25 and 26 conductively connected with the bump electrodes 11 and 12 are formed on the surface of the thermoplastic resin layer 23 by using the same method as in the second embodiment.

The thermoplastic resin layer 23 is divided along one-dot lines shown in FIG. 5D to form electronic devices 20P′, each of which includes the electronic component 10, the thermoplastic resin split layer 23B, and the conductors 25 and 26.

In the present embodiment, the degree of limitations to the material and shape of the supporter 17 is decreased by forming the supporter 17 for integrating the electronic components 10 separately from the conductors 25 and 26 formed later, whereby the material and shape of the supporter 17 can be freely selected.

Fifth Embodiment

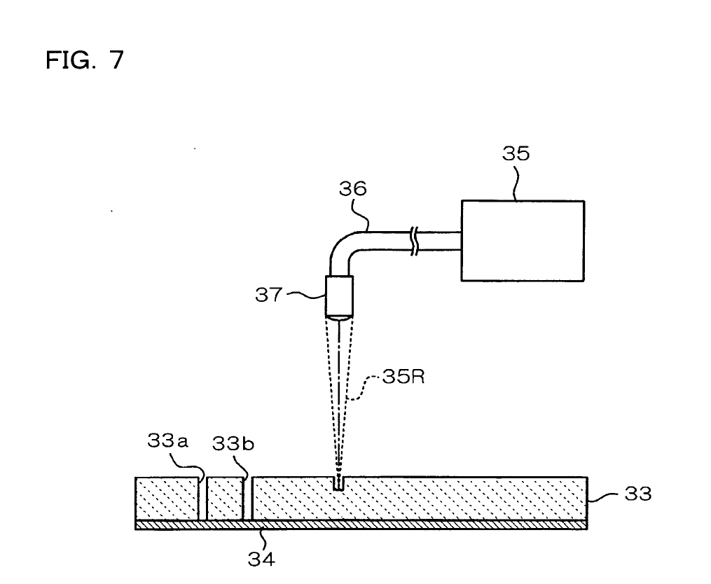

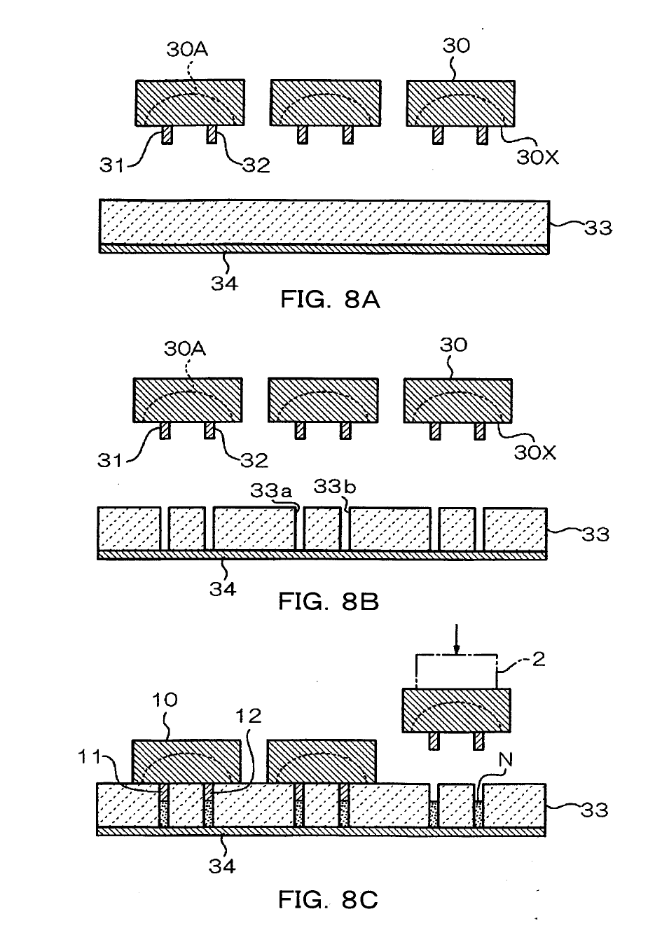

The fifth embodiment according to the present invention is described below with reference to FIG. 7 and FIGS. 8A to 8C. The feature of the present embodiment is that penetrating holes 33a and 33b are formed as shown in FIG. 8B in a thermoplastic resin layer 33 shown in FIG. 8A. As shown in FIG. 8A, the projection height of bump electrodes 31 and 32 of an electronic component 30 is set to be smaller than the thickness of the thermoplastic resin layer 33. A conductor layer 34 is disposed on one surface of the thermoplastic resin layer 33. The conductor layer 34 may adhere to one surface of the thermoplastic resin layer 33.

The penetrating holes 33a and 33b are formed by a laser beam 35R generated by a laser 35 as shown in FIG. 7. In this hole formation method, the thermoplastic resin is caused to melt and burn down by applying the laser beam 35R generated by the laser 35 to the thermoplastic resin layer 33. In the example shown in FIG. 7, the laser beam 35R is applied to the thermoplastic resin layer 33 from the laser 35 through an optical fiber 36 and an optical system 37. The penetrating holes 33a and 33b are formed corresponding to the formation pitch of the bump electrodes 31 and 32. The diameter of the penetrating holes 33a and 33b is about 10 μm to 50 μm, for example. The diameter of the penetrating holes 33a and 33b may be approximately the same as the diameter of the bump electrodes 31 and 32. The diameter of the penetrating holes 33a and 33b may be smaller than or greater than the diameter of the bump electrodes 31 and 32. The conductor layer 34 faces the penetrating holes 33a and 33b formed in this manner.

Then, a conductive material N is disposed in the penetrating holes 33a and 33b (see FIG. 8C). As the conductive material N, a material obtained by melting powder of a low-melting-point metal such as Sn, IN, or Zn by heating, a columnar product of the above metal, a material obtained by curing a conductive fluid material in which conductive particles are dispersed such as a metal paste, or the like may be used. The conductive material N is conductively connected with the conductor layer 34. The conductor layer 34 and the conductive material N may be bonded through an alloy junction by performing a heat treatment or the like. The entire penetrating holes 33a and 33b are not necessarily filled with the conductive material N. The conductive material N may remain at a position lower than the surface of the thermoplastic resin layer 33 opposite to the conductor layer 34 as shown in FIG. 8C insofar as the conductive material N is conductively connected with the conductor layer 34.

As shown in FIG. 8C, the electronic component 30 is bonded to the thermoplastic resin layer 33. In this case, the electronic component 30 is pressed against the thermoplastic resin layer 33 so that the bump electrodes 31 and 32 coincide with the penetrating holes 33a and 33b. In particular, the bump electrodes 31 and 32 are inserted into the penetrating holes 33a and 33b while heating the electronic component 30 using the pressure heating head 2 so that the bump electrodes 31 and 32 are conductively connected with the conductive material N. The bump electrodes 31 and 32 and the conductive material N may be alloyed by heating.

Then, conductors are formed by patterning the conductor layer 34 in the same manner as in the first embodiment, and the thermoplastic resin layer 33 is divided in units of the electronic components 30 to form electronic devices.

In the present embodiment, since the bump electrodes 31 and 32 are conductively connected with the conductors through the conductive material N by disposing the conductive material N in the penetrating holes 33a and 33b formed in the thermoplastic resin layer 33, high degrees of freedom can be secured for the projection height of the bump electrodes 31 and 32 and the thickness of the thermoplastic resin layer 33.

After the penetrating holes 33a and 33b are formed in the thermoplastic resin layer 33 and the electronic component 30 is mounted in the thermoplastic resin layer 33 so that the bump electrodes 31 and 32 are inserted into the penetrating holes 33a and 33b, the penetrating holes 33a and 33b may be filled with the conductive material N from the opposite side of the penetrating holes 33a and 33b so that the conductive material N is conductively connected with the bump electrodes 31 and 32, and the conductors may be formed so that the conductors are conductively connected with the conductive material N.

Sixth Embodiment

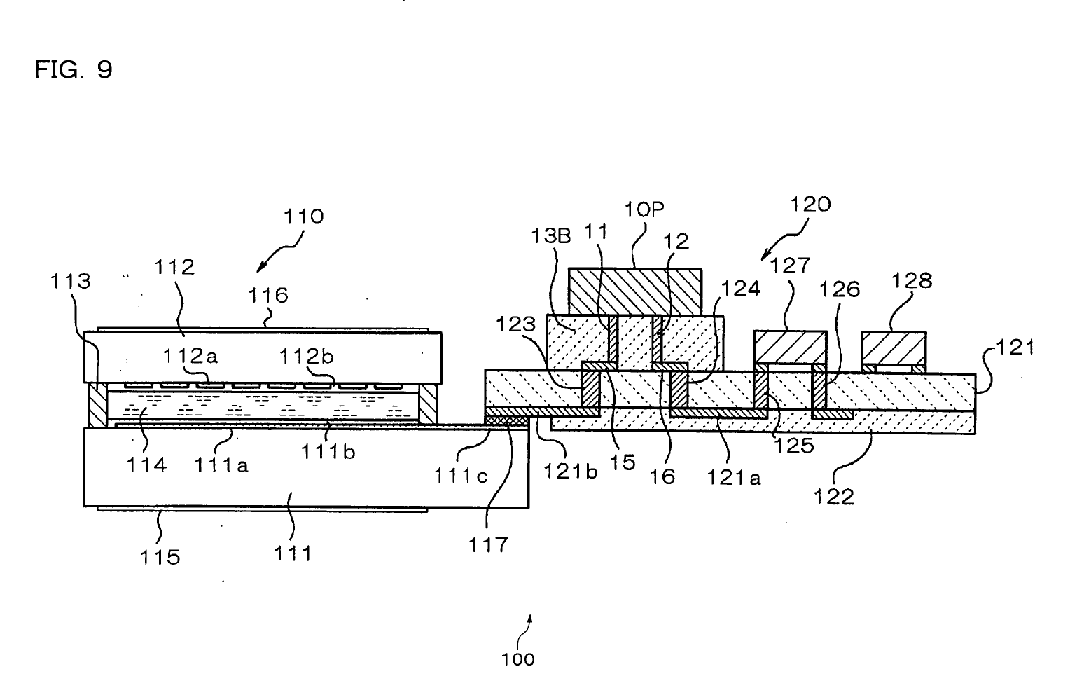

The sixth embodiment showing an electro-optical device according to the present invention is described below with reference to FIG. 9. In the present embodiment, an electro-optical device 100 includes the electronic device 10P manufactured by the above-described embodiment. The following description is given taking the case of using the electronic device 10P as an example. However, the electronic device 10P′, 20P, or 30P, or the electronic device formed by the fifth embodiment may be used in the same manner as the electronic device 10P. The electronic device 10P may include a circuit which generates a drive signal for driving the electro-optical device in the electronic structure region (specifically, mounting unit of a liquid crystal drive IC chip).

The electro-optical device 100 in the present embodiment is a liquid crystal display device, and includes an electro-optical panel 110 (liquid crystal panel) and a circuit board 120 (flexible interconnect substrate) mounted on the electro-optical panel 110. The electro-optical panel 110 is formed by attaching a pair of substrates 111 and 112 formed of glass, plastic, or the like using a sealing material 113. An electro-optical substance 114 such as a liquid crystal is sealed between the substrates 111 and 112. A transparent electrode 111a formed of a transparent conductor such as ITO is formed on the inner surface of the substrate 111, and an alignment film 111b covers the transparent electrode 111a. A transparent electrode 112a is formed of the same material as described above on the inner surface of the substrate 112, and an alignment film 112b covers the transparent electrode 112a. Polarizers 115 and 116 are respectively disposed on the outer surfaces of the substrates 111 and 112.

In the circuit board 120, an interconnect pattern 121a is formed of Cu or the like on the surface of an insulating substrate 121 (lower surface in FIG. 8). The insulating substrate 121 is formed of a thermosetting resin such as epoxy or polyimide, or a thermoplastic resin such as polyester, polyamide, aromatic polyester, aromatic polyamide, tetrafluoroethylene, or polyimide. The interconnect pattern 121a is covered with a protective film 122 excluding a terminal section such as a connection terminal section 121b connected with the electro-optical panel 110. The connection terminal section 121b is conductively connected with an interconnect 111c on the surface of the substrate 111 through an anisotropic conductive film 117. The interconnect 111c is conductively connected with the transparent electrodes 111a and 112a, and pulled toward a substrate overhang section of the substrate 111 (section overhanging outward from the external shape of the substrate 112).

Connection pads 123, 124, 125, and 126 conductively connected with the interconnect pattern 121a are exposed from the surface (upper surface in FIG. 8) of the insulating substrate 121 opposite to the surface on which the interconnect pattern 121a is formed. Various electronic components 127 and 128 are mounted on the connection pads. The electronic device 10P is mounted on the connection pads 123 and 124. The electronic device 10P is pressed against the circuit board 120 in a state in which the electronic device 10P is heated by using a pressure heating head or the like. This causes a part of the thermoplastic resin split layer 13B to soften or dissolve, and the thermoplastic resin split layer 13B covers the circumference of the conductive connection sections between the conductors 35 and 36 and the connection pads 123 and 124, whereby the space between the electronic device 10P and the insulating substrate 121 is completely closed. This makes it unnecessary to perform an injection operation of an underfill resin, whereby the mounting operation is facilitated. Moreover, since occurrence of voids can be prevented, electrical reliability of the mounting structure can be increased.

In particular, since the insulating substrate 121 of the circuit board in the present embodiment is formed of a thermoplastic resin, weldability with the thermoplastic resin split layer 13B of the electronic device 10P is high, whereby a mounting structure provided with sufficient holding power and sealing performance can be obtained.

Seventh Embodiment

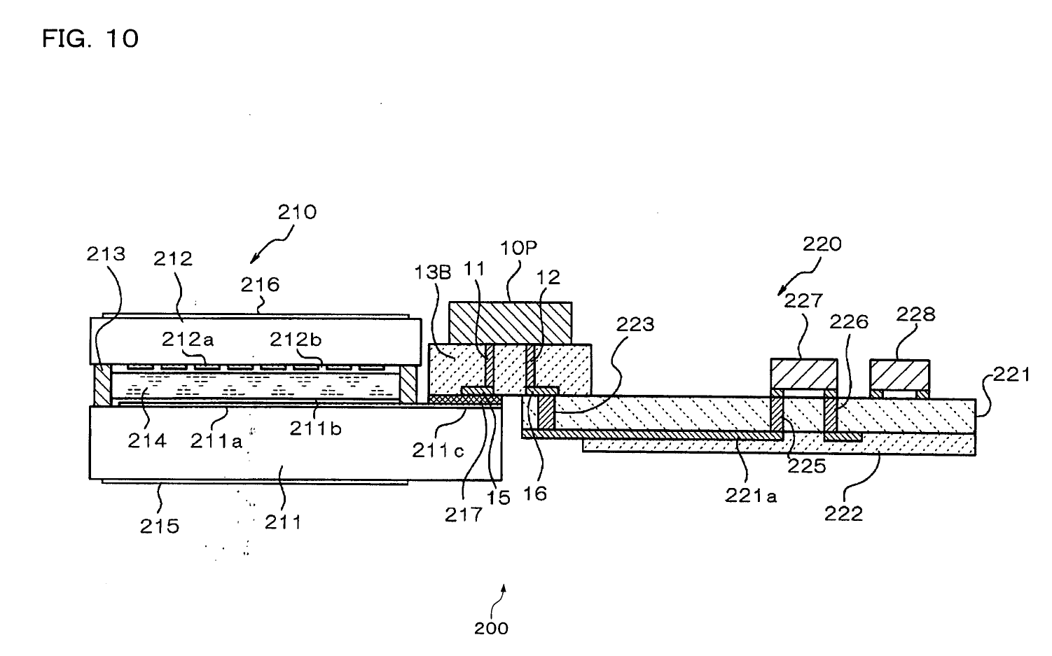

The seventh embodiment showing an electro-optical device according to the present invention is described below with reference to FIG. 10. An electro-optical device 200 in the present embodiment includes an electro-optical panel 210 which is the same as the electro-optical panel 110 in the sixth embodiment, and a circuit board 220 which is almost the same as the circuit board 120 in the sixth embodiment. Therefore, the corresponding constituent elements including substrates 211 and 212, transparent electrodes 211a and 212a, an interconnect 211c, alignment films 211b and 212b, a sealing material 213, an electro-optical substance 214, polarizers 215 and 216, an interconnect pattern 221a, a protective film 222, connection pads 223, 225, and 226, and electronic components 227 and 228 are the same as those in the sixth embodiment. Therefore, description of these constituent elements is omitted.

In the present embodiment, the electronic device 10P is mounted on the interconnect 211c of the electro-optical panel 310 and the connection pad 223 of the circuit board 220, whereby the circuit board 220 is connected with the electro-optical panel 210 through the electronic device 10P. In the example shown in FIG. 10, the electronic device 10P is directly mounted on the circuit board 220 in the same manner as in the sixth embodiment. The electronic device 10P is conductively connected with the interconnect 211c through an anisotropic conductive film 217. However, the conductor 15 of the electronic device 10P may be directly conductively connected with the interconnect 211c.

Eighth Embodiment

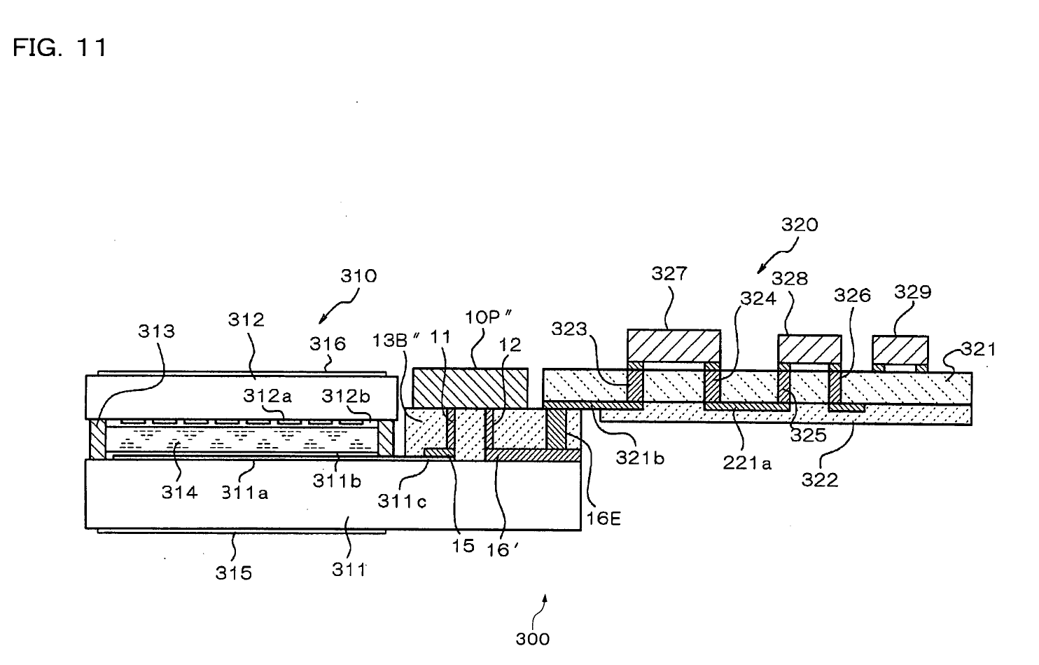

The eighth embodiment showing another electro-optical device according to the present invention is described below with reference to FIG. 11. An electro-optical device 300 (liquid crystal display device) in the present embodiment includes an electro-optical panel 310 and a circuit board 320 mounted on the electro-optical panel 310. The electro-optical panel 310 has almost the same structure as that of the electro-optical panel 110 in the sixth embodiment. Substrate 311 and 312, transparent electrodes 311a and 312a, alignment films 311b and 312b, an interconnect 311c, a sealing material 313, an electro-optical substance 314 such as a liquid crystal, and polarizers 315 and 316 are the same as those described in the sixth embodiment. Therefore, description of these constituent elements is omitted.

In the circuit board 320, an insulating substrate 321, an interconnect pattern 321a, a connection terminal section 321b, a protective film 322, connection pads 323, 324, 325, and 326, and electronic components 327, 328, and 329 are the same as those described in the sixth embodiment. Therefore, description of these constituent elements is omitted.

The present embodiment differs from the sixth embodiment in that an electronic device 10P″ is directly mounted on the surface of the substrate 311 which makes up the electro-optical panel 310. The present embodiment differs from the seventh embodiment in that the electronic device 10P″ is mounted only on the substrate 311. The electronic device 10P″ is directly mounted on the substrate 311 in a state in which the conductors 15 and 16′ are conductively connected with the interconnect 311c pulled toward the substrate overhang section of the substrate 311 in the same manner as described above. The substrate 311 is formed of glass, plastic, or the like. In the present embodiment, a thermoplastic resin split layer 13B″ softens or dissolves by disposing the electronic device 10P″ on the substrate 311 and applying pressure and heat to the electronic device 10P″, whereby the electronic device 10P″ adheres to the substrate 311.

The present embodiment also differs from the above-described embodiments in that the circuit board 320 is mounted on the electronic device 10P″. A connection pad 16E which is exposed from the surface of the thermoplastic resin split layer 13B″ and is conductively connected with the conductor 16′ is provided in the electronic device 10P″. The connection terminal section 321b of the circuit board 320 is conductively connected with the connection pad 16E. Since the electronic device 10P″ is formed by dividing the thermoplastic resin layer 13 as described above, the conductor pattern and the like can be freely set. This allows formation of the conductor 16′, the connection pad 16E, and the like.

In the present embodiment, since the electronic device 10P″ is directly mounted on the substrate 311 of the electro-optical panel 310 and the circuit board 320 is mounted on the electronic device 10P″, the number of mounting steps for the electro-optical panel 310 can be reduced to one.

The present invention is not limited to the above-described examples shown in the drawings. Various modifications and variations can be made within the scope and spirit of the present invention. The above-described embodiment of the electro-optical device illustrates a passive matrix liquid crystal display device as an example. However, the present invention can be applied not only to the passive matrix liquid crystal display device shown in the drawings, but also to an active matrix liquid crystal display device (liquid crystal display device including a thin-film transistor (TFT) or thin-film diode (TFD) as a switching device, for example). Moreover, the present invention can also be applied to various electro-optical devices such as an electroluminescent device, an organic electroluminescent device, a plasma display device, an electrophoresis display device, and a device using an electron emission element (field emission display, surface-conduction electron-emitter display, and the like) in addition to the liquid crystal display device.

The present invention is not limited to the above-described embodiments. Various modifications of the present invention are possible. For example, the present invention includes configurations substantially the same as the configurations described in the embodiments (in function, in method and effect, or in objective and effect). The present invention also includes a configuration in which an unsubstantial portion in the above-described embodiments is replaced. The present invention also includes a configuration having the same effects as the configurations described in the embodiments, or a configuration capable of achieving the same objective. Further, the present invention includes a configuration in which a known technique is added to the configurations described in the embodiments.

1. A method of manufacturing an electronic device, comprising:
mounting a plurality of electronic components to a thermoplastic resin layer so that the bump electrode is installed in the thermoplastic resin layer, each of the electronic components including a bump electrode;
forming a conductor conductively connected with the bump electrode on a surface of the thermoplastic resin layer opposite to a surface on which the electronic components are mounted; and
dividing the thermoplastic resin layer in units of each of the electronic components.

2. The method of manufacturing an electronic device as defined in claim 1,
wherein, in the step of mounting the electronic components, the electronic component or the thermoplastic resin layer is heated.

3. The method of manufacturing an electronic device as defined in claim 1,
wherein, in the step of mounting the electronic components, the electronic components are mounted so that the bump electrode passes through the thermoplastic resin layer and is exposed from the surface of the thermoplastic resin layer opposite to the surface on which the electronic components are mounted.

4. The method of manufacturing an electronic device as defined in claim 1,
wherein, in the step of mounting the electronic components, the electronic components are mounted so that the bump electrode is conductively connected with a conductor layer which has been disposed in advance on the surface of the thermoplastic resin layer opposite to the surface on which the electronic components are mounted, and
wherein, in the step of forming the conductor, the conductor is formed by patterning the conductor layer.

5. The method of manufacturing an electronic device as defined in claim 1, comprising:
before the step of mounting the electronic components, forming a penetrating hole in the thermoplastic resin layer and disposing a conductive material in the penetrating hole,
wherein, in the step of mounting the electronic components, the bump electrode is inserted into the penetrating hole and conductively connected with the conductive material.

6. The method of manufacturing an electronic device as defined in claim 1,
wherein, in the step of mounting the electronic components, the thermoplastic resin layer is formed to enclose the electronic components by molding.

7. The method of manufacturing an electronic device as defined in claim 6,
wherein, in the step of mounting the electronic components, the molding is performed in a state in which the electronic components are supported by a supporter.

8. The method of manufacturing an electronic device as defined in claim 7,
wherein the supporter is formed of a conductive material and conductively connected with the bump electrode, and
wherein, in the step of forming the conductor, the conductor is formed by patterning the supporter.

9. The method of manufacturing an electronic device as defined in claim 1,
wherein, in the step of forming the conductor, the conductor is formed by applying a fluid material to the surface of the thermoplastic resin layer opposite to the surface on which the electronic components are mounted, and curing the fluid material.

10. The method of manufacturing an electronic device as defined in claim 9,
wherein, in the step of forming the conductor, the fluid material in the form of liquid is discharged as a droplet.

11. The method of manufacturing an electronic device as defined in claim 9,
wherein, in the step of forming the conductor, the fluid material in the form of paste is printed.

12. The method of manufacturing an electronic device as defined in claim 1,
wherein the step of forming the conductor includes forming a resist layer which has a patterned opening on the surface of the thermoplastic resin layer opposite to the surface on which the electronic components are mounted, and
wherein the conductor is formed on a portion of the thermoplastic resin layer exposed from the opening.

13. The method of manufacturing an electronic device as defined in claim 12,
wherein the step of forming the conductor includes discharging a solvent containing conductive particles, and
wherein the resist layer is formed so that an upper surface of the resist layer has an affinity to the solvent lower than an affinity of the surface of the thermoplastic resin layer opposite to the surface on which the electronic components are mounted.

14. The method of manufacturing an electronic device as defined in claim 12, further comprising removing the resist layer after forming the conductor.

15. A method of manufacturing an electro-optical device, comprising:
mounting an electronic device manufactured by using the manufacturing method as defined in claim 1 on a circuit board by thermocompression bonding; and
mounting the circuit board on an electro-optical panel.

16. A method of manufacturing an electro-optical device, comprising:
mounting an electronic device manufactured by using the manufacturing method as defined in claim 1 on a substrate which forms an electro-optical panel by thermocompression bonding.
